(19) United States
(12) Patent Application Publication
(10) Pub. No.: US 2011/0100434 A1
(43) Pub. Date: May 5, 2011

(54) ATTACHMENT MEANS FOR SOLAR PANELS

(75) Inventor: Jan Van Walraven, Mijdrecht (NL)

(73) Assignee: J. VAN WALRAVN HOLDING B.V., Mijdrecht (NL)

(21) Appl. No.: 12/863,252

(22) PCT Filed: Dec. 16, 2008
(86) PCT No.: PCT/NL2008/000276

§ 371 Date: Jan. 18, 2011

(30) Foreign Application Priority Data
Jan. 18, 2008 (NL) 2001200

(51) Int. Cl. H01L 31/048; E04D 13/18; H01L 31/18

(52) U.S. Cl. 136/251; 29/428

(57) ABSTRACT

The invention relates to an attachment system for the attachment of a solar panel. The attachment system comprises a support structure for supporting an underside of the panel. Furthermore, the attachment system comprises a pin-shaped attachment member which is connected to the support structure and, in use, extends along one of the edges of the panel and substantially at right angles to the panel. A clamping member which is coupled to the pin-shaped attachment members, in a fitted state, is situated over an edge region on the upper side of the panel and is clamped against the respective edge region by means of the pin-shaped attachment member in order to fasten the panel against the support structure. The clamping member, at least in the pre-fitting state, is rotatable with respect to the pin-shaped attachment member in a plane at right angles to the pin-shaped attachment member. The clamping member has a peripheral edge and is rotatable with respect to a panel to be fitted or fitted on the support structure into an inactive position in which that portion of the peripheral edge which is turned towards the respective panel is not situated over the edge region of the panel, so that fitting a panel on or removing a panel from the support structure is made possible.

The invention relates to the attachment of solar panels and solar collectors. The term solar panels mentioned in the text below is also intended to include solar collectors.

More particularly, the invention relates to an attachment system for the attachment of solar panels according to the preamble of claim 1.

An attachment system of this type is known.

DE 102 33 973 discloses an attachment system in which a solar panel is attached to a substructure comprising profiled-section rails. The profiled-section rails are of the so-called C-shaped type having an upper side in which two flanges delimit a longitudinal slot. The known system uses an attachment assembly to attach the panels to the profiled-section rails. The attachment assembly comprises a hammerhead nut provided with a threaded bore which, in use, is arranged in the C-shaped profiled-section rail and engages with the inner side of the flanges, a bottom clamping plate which is connected to the hammerhead nut by means of a retaining element, an upper clamping plate and a screw bolt which extends through bores in the clamping plates and is screwed into the hammerhead nut. In use, the attachment assemblies are provisionally fitted to the profiled-section rails, following which the panel edges of the panel are pushed between the bottom and top clamping plate of the attachment assemblies associated with the relevant panel. Subsequently, the bolt can be tightened and the panel edge is clamped between the two clamping plates and the entire combination is clamped securely against the profiled-section rails. For each attachment assembly, panel edges can be clamped in on either side of the bolt. A drawback of this known attachment system is the fact that the solar panels have to be manoeuvred into awkward positions in order to be able to slide their edges between the clamping plates of the associated attachment assemblies.

It is an object of the invention to provide an improved attachment system by means of which the solar panels can be fitted in a simpler manner.

This object is achieved according to the invention by means of an attachment system according to claim 1.

The attachment system according to the invention comprises a support structure for supporting an underside of the panel, a pin-shaped attachment member which is connected to the support structure and, in use, extends along one of the edges of the panel and substantially at right angles to the panel, as well as a clamping member which is coupled to the pin-shaped attachment member and, in a fitted state, is situated over an edge region on the upper side of the panel and is clamped against the respective edge region by means of the pin-shaped attachment member in order to fasten the panel against the support structure. The attachment system according to the invention is characterized by the fact that the clamping member has a peripheral edge, and that the clamping member, at least in a pre-fitting state, is rotatable with respect to the pin-shaped attachment member in a plane at right angles to the pin-shaped attachment member, with the clamping member being rotatable with respect to a panel to be fitted or fitted on the support structure into an inactive position in which that portion of the peripheral edge which is turned towards the respective panel is not situated over the edge region of the panel, so that fitting a panel on or removing a panel from the support structure is made possible.

The attachment system according to the invention offers the possibility of turning the clamping member into an inactive position so that the panel can be fitted on the support structure without the clamping member forming an obstruction. The panels can be fitted on the support structure by means of a simple movement, following which they are locked between the support structure and the clamping member in a quick and simple manner by turning the clamping member out of its inactive position. The above makes fitting easier and quicker.

Preferred embodiments of the attachment system are defined in the dependent claims.

The invention furthermore relates to a method for mounting several solar panels next to one another on a support structure according to claim 25.

According to the invention, the method for mounting several solar panels next to one another on a support structure comprises the following method steps:
at least three pin-shaped attachment members together with clamping members coupled thereto are arranged on the support structure at such a distance from one another that a solar panel can be fitted between each pair of clamping members, with each of the clamping members being rotatable with respect to the associated pin-shaped element about an axis of rotation which runs parallel to or coincides with the centre axis of the pin-shaped attachment member, in which the clamping member has a peripheral edge, and in which the clamping member can be moved to an inactive position by rotation;
the clamping members associated with a first panel to be fitted are moved to an inactive position by rotation of the clamping member, in which position that portion of the peripheral edge of the clamping member which is turned towards the respective panel does not extend over the edge region of the panel;
the first solar panel is fitted against the support structure between the associated attachment members, in which opposite edges of the panel are situated against the pin-shaped attachment members or against spacers extending around the attachment members;
the clamping members associated with the first panel are rotated from the inactive position to an active position in which they extend over the edge of the first panel and lock the first panel against the support structure, with the at least one clamping member which is associated with the first panel and is also associated with a second panel to be fitted next to the first panel being oriented in such a manner that it is in an inactive position with respect to the edge region of the second panel to be fitted;
the at least one other clamping member associated with the second panel to be fitted is rotated in such a manner that it is moved into the inactive position with respect to the second panel;
the second solar panel is fitted against the support structure between the associated attachment members, with opposite edges of the panel being situated against the pin-shaped attachment members or against spacers extending around the attachment members;
the at least one clamping member associated both with the first and with the second panel is rotated into an active position in which it extends over the edge of the first and the second panel and locks the first and second panel against the support structure;
the at least one other clamping member associated with the second panel is rotated into an active position in which it extends over the edge of the second panel and locks the second panel against the support structure.

The method according to the invention provides a simple way of fitting solar panels on a support structure, by means of which a significant time saving can be achieved compared to known methods for fitting solar panels on a support structure.

The invention will be described in more detail in the following description with reference to the drawing, in which:

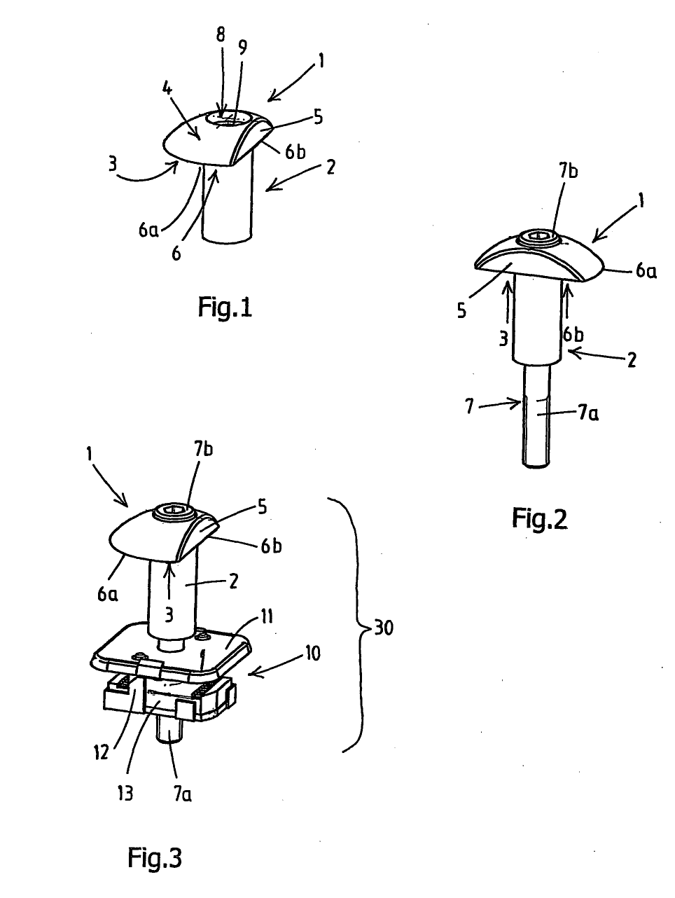

FIG. 1 shows a perspective view of a preferred embodiment of a clamping member for an attachment system according to the invention,

FIG. 2 shows a perspective view of the clamping member from FIG. 1 with a bolt extending through the said clamping member,

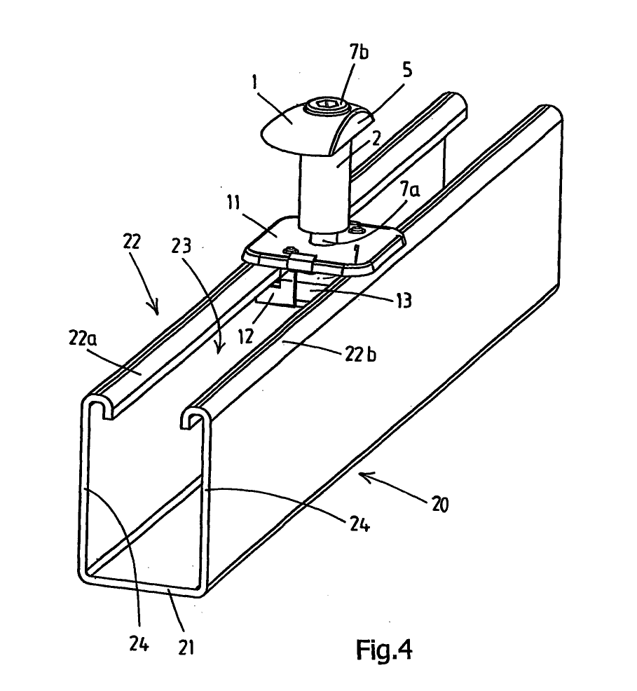

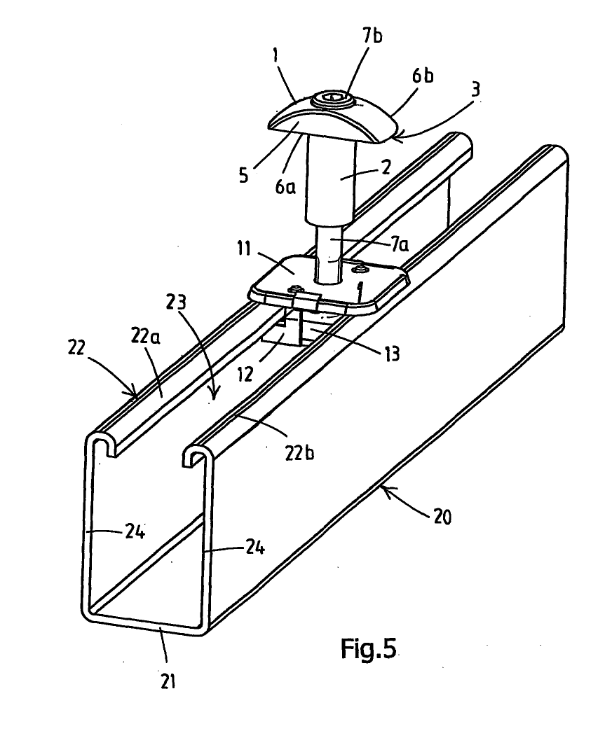

FIG. 3 shows a perspective view of an assembly of the clamping member with the bolt from FIG. 2 combined with an attachment assembly for the attachment of the clamping member to a profiled rail,

FIG. 4 shows a perspective view of a profiled rail with the assembly from FIG. 3 fitted thereon, in which the clamping member is in an inactive position,

FIG. 5 shows a perspective view of a profiled rail with the assembly from FIG. 3 fitted thereon, in which the clamping member is in an active position,

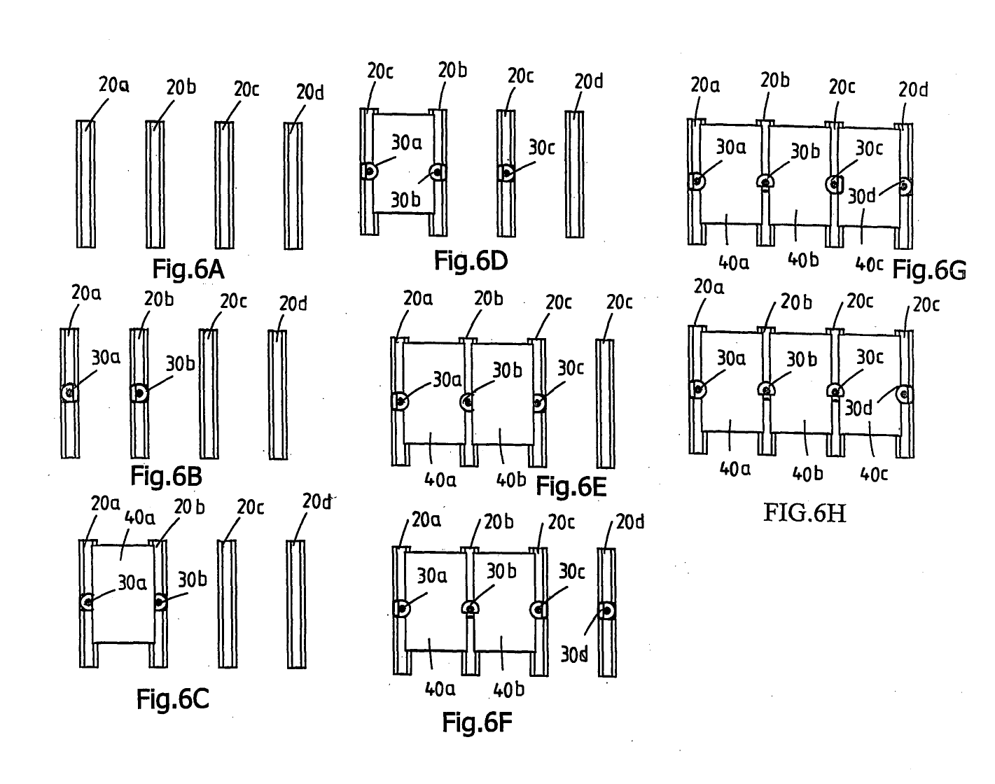

FIG. 6A-6H diagrammatically illustrate how several solar panels are attached to a support structure, and

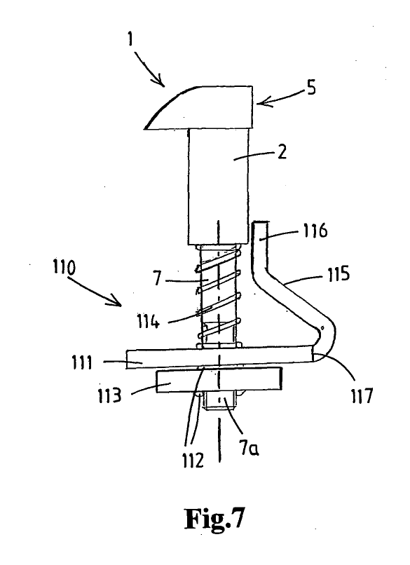

FIG. 7 shows a side view of an assembly of the clamping member with the bolt from FIG. 2 combined with another attachment assembly for the attachment of the clamping member to a profiled rail.

FIG. 1 shows a preferred embodiment of a clamping member 1 which is integrally formed with a bush 2. The clamping member 1 has a bore which is aligned with the bore of the bush 2. The clamping member 1 is substantially shaped in the form of a spherical segment having a spherical surface 4 and a flat face 3. The bush 2 extends from the flat face of the spherical segment 3.

On one side, the spherical segment is flattened, resulting in a flat side 5. The flat face 3 thus has a peripheral edge 6 with a portion in the shape of an arc of a circle 6a and a straight portion 6b. The flat side 5 is in the same plane as that portion on the corresponding side of the bush 2 which protrudes furthest.

It should be noted that the clamping member may also have a shape which differs from that of a spherical segment. The clamping member may, for example, also be flat or may be block-like and may have a different peripheral shape, for example triangular, rectangular or may be in the shape of a flattened ellipse.

The clamping member 1 and the bush 2 are preferably made of plastic by means of, for example, injection-moulding, but could also, for example, be made of metal. The figures show the preferred embodiment in which the clamping member 1 and the bush 2 are integrally formed, but this is not imperative. In the context of the present invention, it is also possible for these to be separate parts. The fact that the bush 2 and the clamping member 2 are integrally formed offers the advantage that fewer separate parts are required during installation.

The clamping member 1 is detachably coupled to a bolt 7. FIG. 2 shows how the bolt shank 7a of the bolt 7 extends through the bore in the clamping member 1 and the bush 2. On that side which is facing away from the bush 2, the clamping member 1 is provided with arecess 8 which has a larger diameter than the bore and which can accommodate the bolt head 7b. As a result thereof, the bolt head 7b is neatly concealed inside the clamping member in the fitted state, which not only results in a more agreeable appearance, but also increases safety as objects, such as the solar panels 40, cannot hit the bolt head, for example during installation activities, and thus become damaged. At the transition between the recess 8 and the bore, an annular stop face 9 is formed against which the underside of the bolt head 7b lies. On the peripheral wall, the recess 8 is preferably provided with ridges (not shown) which engage with the outer periphery of the bolt head 7b in order to retain the latter. The clamping member 1 is rotatable about the bolt shank 7a. If ridges are present in the recess 8, the retaining force of the ridges has to be overcome in order to rotate the clamping member 1 with respect to the bolt.

The bolt 7 can be coupled to an attachment assembly 10 as is illustrated in FIG. 3. The attachment assembly 10 comprises an elongate anchor part 13, a bearing plate 11 and a support 12 which connect the anchor part 13 and the bearing plate 11 to one another. Attachment assemblies of this type are known and readily commercially available, for example under the trade name “RapidStrut® sliding nuts” produced by the applicant.

The attachment assembly 10 is designed to attach a bolt or a threaded rod to a profiled-section rail 20 (see FIG. 4) of the type having a bottom 21, an upper side 22 situated opposite the bottom 21 and comprising two flanges 22a, 22b which delimit a longitudinal slot 23 extending along the entire length, as well as side walls 24 which connect the bottom to the upper side of the profiled section. FIG. 4 shows a so-called “strut section” having inwardly bent flanges. Another variant of said type of section is a so-called “C section”.

The support 12 of the attachment assembly 10 is preferably made from plastic, but may also be made of metal. Preferably, the support 12 is provided with spring means (not shown) which push the elongate anchor part 13 in the direction of the bearing plate 11. In use, the elongate anchor part 13 is aligned in the longitudinal direction with the longitudinal slot 23, after which the anchor part 13 is introduced into the profiled-section rail 20 from above through the slot 23. The bearing plate 11 comes to lie against the upper side of the flanges 22a, 22b. Subsequently, the attachment assembly 10 is turned, preferably by a quarter turn, as a result of which the anchor part 13 engages behind the underside of the flanges 22a, 22b. The spring means of the support push the anchor part 13 against the underside of the flanges 22a, 22b, as a result of which the attachment assembly 10 is clamped onto the profiled-section rail 20 in a pre-fitting state.

The anchor part 13 is provided with a threaded bore which can interact with a threaded bolt or the like. The bearing plate 11 is also provided with a hole through which a bolt or the like can extend.

FIG. 3 shows how the attachment assembly 10 and the clamping member 1 are combined with the bush 2 and the bolt 7 to form an assembly 30. Preferably, the assembled assembly is fitted on a profiled-section rail 20 as is illustrated in FIG. 4. However, it is also possible to fit an attachment assembly 10 on a profiled-section rail first, followed by the bolt 7 with the clamping member and the bush 2. It should be noted that in the context of the definition of the invention, the attachment assembly 10 is considered to form part of the support structure of which the profiled-section rails 20 likewise form part.

According to a preferred embodiment of the attachment system according to the invention, several profiled-section elements are poitioned next to one another. The profiled-section elements form part of a support structure which may also comprise other components.

By way of example, FIG. 6A shows four parallel profiled-section rails 20a-20d positioned at a distance from one another.

FIG. 6B shows how one assembly 30 (see FIG. 3) is fitted on each of the two neighbouring profiled-section rails 20a and 20b, as is illustrated in FIG. 4. The assembly 30 on profiled section 20a and 20b, respectively, is denoted by reference numeral 30a and 30b, respectively. The clamping member 1 on the profiled section 20a is turned in such a manner that the flat side 5 is turned towards the other profiled section 20b. The clamping member 1 on the profiled section 20b is in turn turned in such a manner that the flat side 5 is turned towards the profiled section 20a. The clamping members 1 on the profiled sections 20a and 20b are now in the inactive position. FIG. 4 shows this inactive position in more detail.

FIG. 6C shows how a first solar panel 40a is fitted between the assemblies 30a and 30b. As the clamping members 1 are in the inactive position with respect to this first panel 40a, the panel 40a can be fitted between the clamping members 1 against the bearing plates 11 of the respective assemblies 30a and 30b. For this reason, the bearing plates 11 are preferably made from plastic in order to prevent, as far as possible, damage to the panels, for example as a result of contact corrosion. It is also possible for the bearing plates 11 to be made of metal and to provide them with a protective layer of plastic or rubber on the side which is turned away from the anchor part 13. It should also be possible to provide an additional ring made of plastic or rubber on the side which is turned away from the anchor part in order to prevent damage to the panels 40.

The respective side edges of the panel 40a bear against the bush 2 of the assembly 30a and 30b, respectively. The bush 2 therefore serves as a spacer and prevents a lateral movement of the panel 20a. The bush 2 is preferably made of plastic in order to prevent damage of the side edge of the panel, resulting for example from contact corrosion. The bush 2 preferably has an axial length which is at least half the thickness of a panel 40 to be attached. As a result thereof, the bush is clamped in along a sufficiently long axial length between two neighbouring panels 40, which makes it impossible for the bolt 7 to be able to tilt in the pre-fitting state. The bush 2 has a length which is not more than the thickness of the panel 40. The maximum length of the bush 2 is equal to the thickness of the panel 40.

FIG. 6D shows how the clamping members 1 are rotated through 180° to an active position with respect to panel 40a in which the clamping members 1 extend over the edge regions of the panel 40a and thus lock the panel 40a against the bearing plates 12 and thus against the support structure. The flat side 5 of the clamping member 1 of the assembly 30b is now turned towards the profiled section 20c. The clamping member 1 of the assembly 30b is now in an inactive position with respect to the panel 40b which is to be fitted next thereto. FIG. 6D furthermore shows that an assembly 30c is fitted on a third profiled-section rail 20c and is also turned to an inactive position with respect to the panel 40b which is to be fitted.

FIG. 6E shows how the panel 40b is fitted between the assemblies 30b and 30c as has already been described above with respect to panel 40a.

FIG. 6F shows how the clamping member 1 of the assembly 30b is turned through a quarter turn to an active position with respect to the first panel 40a and the second panel 40b. In this active position, which is shown in more detail in FIG. 5, the flat side 5 of the clamping member 1 extends at right angles to the longitudinal direction of the profiled section 20b and the clamping member 1 extends both over the edge region of the first panel 40a and the second panel 40b and locks these panels 40a and 40b against the support structure. The clamping member 1 of the assembly 30c is turned through 180° and is in an active position with respect to panel 40b and an inactive position with respect to a third panel 40c which is to be fitted on the other side of the assembly 30c.

FIGS. 6G and 6H show the fitting and fastening of the third panel 40c which is carried out in a manner similar to that described above with respect to the second panel 40b.

After the panels 40 have been fitted in the structure and locked by the clamping members 1, the bolts 7 can be tightened in order to clamp the panels 40 tightly against the support structure.

It should be noted that the invention is not limited to support structures having support profiled sections. It is, for example, also possible to fixedly attach the clamping member 1 and the bush 2 to a support surface by means of a screw. Thus, for example, the clamping member 1 and the bush 2 could be attached to a wooden support structure using a wood screw.

Furthermore, it should be noted that in the example of FIGS. 6A-6H only one clamping member 1 is provided for each side of each panel 40. It will be clear that several clamping members 1 may also be provided for each side of the panel 20.

It is also pointed out that although the example of FIGS. 6A-6H shows that the panels 40 extend between the profiled-section rails 20, it is also possible for the panels 40 to be fitted transversely over the profiled-section rails.

FIG. 7 shows an alternative assembly of a clamping member 1 and an attachment assembly 110 for attaching the clamping member 1 on a profiled-section rail. The attachment assembly 110 comprises an elongate anchor part 113 and a bearing plate 111. The anchor part 113 has a threaded bore which is preferably provided with a plastic insert 112, as is shown in the figure. The bolt 7 which extends through the clamping member 1 in the manner described above is connected to the elongate anchor part 113 as a result of the fact that the insert 112 engages in a clamping manner with the bolt shank 7a which extends through the bore. As an alternative to an insert 12, the bolt 7 could also be connected to the anchor part 113 by means of some adhesive. If the bolt 7 is then tightened after preassembly, the resistance of the clamping insert 112 on the bolt shank 7a is overcome or the adhesive connection is broken.

Between the underside of the bush 2 and the side of the bearing plate 111 turned towards the clamping member 1, a spring 114 is preferably provided which pushes away the clamping member 1 of the bearing plate 111. As a result thereof, the head of the bolt 7 is pushed away, and at the same time, the anchor part 113 is pulled against the underside of the bearing plate 111.

In use, the elongate anchor part 113 is aligned with the slot of, for example, a C-shaped profiled-section rail. Subsequently, when the bearing plate 111 is situated on the upper side of the profiled-section rail, the clamping member 1 with the bolt is pushed to the bearing plate 111 counter to the spring force of the spring 114, as a result of which the anchor part 113 is pushed away from the bearing plate 111. As a result thereof, a space is created between the bearing plate 111 and the anchor part 113. Subsequently, the anchor part 113 with the bolt 7 can be turned through a quarter turn, as a result of which the anchor part 113 grips behind the flanges of the profiled rail. When the bolt is released, the anchor part 113 is pulled against the flanges of the profiled rail as a result of the spring force of the spring 114.

In the assembly of FIG. 7, the bearing plate 111 has a supporting strip 115 which is preferably integrally formed, but can also be connected to the bearing plate 111 in any other way. In the illustrated embodiment, the supporting strip 115 extends from an edge 117 of the bearing plate 111 via a kind of swan neck shape in the radial direction inwards. The free end part 116 of the supporting strip 115 extends substantially parallel to the bush 2 of the clamping member 1. In this case, the end part 116 virtually abuts the bush 2. Preferably, on that side which is turned towards the bush, the end part 116 has a radius which substantially corresponds to the external radius of the bush 2. The supporting strip 115 has a width (in the direction at right angles to the plane of the drawing) which is smaller than or equal to the diameter of the bush 2. The bearing plate 111 with the supporting strip 115 can be made of metal, but may also be made from plastic. A metal bearing plate which is coated with plastic is also conceivable.

The bearing plate 111 which, is provided with the supporting strip 115 is mainly advantageous if the assembly 110 is used to clamp only one solar panel 40. If a solar panel 40 is clamped between the clamping member 1 and the bearing plate 111—on the left-hand side in FIG. 7—by tightening the bolt 7, the bush 2 with the clamping member 1 could have a tendency to tilt—to the right in FIG. 7. This tilting might result in the solar panel 40 being clamped in insufficiently. The supporting strip 115 which virtually abuts the bush 2 prevents the abovementioned tilting and ensures that the respective panel 40 is clamped securely. It is also possible to use a different supporting element instead of the supporting strip which is present in the illustrated embodiment.

The assembly 110 can also be used to securely clamp two panels 40. To this end, the bearing plate 111 is turned through a quarter turn with respect to the profiled rail and thus the panels 40. The supporting strip 115 is then situated between the edges of the panels 40 and is then not operational.

The bearing plate 111 which is provided with a supporting strip or another supporting element could also be used for applications other than the attachment system according to the present invention. In particular, the bearing plate could be used in an attachment assembly which is combined with a clamping member which differs from that according to the characterizing part of claim 1 in order to prevent any tilting of said other clamping member.

It should be noted that the figures show two examples of an attachment assembly which should not be interpreted as a limitation. Other attachment assemblies are also possible. For the implementation of the invention, it is not important which specific embodiment the attachment assembly has.

Finally and perhaps superfluously, it should be noted that the above-described shape of the clamping member 1 which has been illustrated in the figures is a preferred embodiment. The clamping member may also be of a different design. The only thing which is important is that the shape of the clamping member offers the possibility to turn the clamping member into an inactive position with respect to a panel in order to be able to fit this panel against the support structure or to remove it therefrom.

1. Attachment system for the attachment of a solar panel, comprising a support structure for supporting an underside of the panel, a pin-shaped attachment member which is connected to the support structure and, in use, extends along one of the edges of the panel and substantially at right angles to the panel, as well as a clamping member which is coupled to the pin-shaped attachment member and, in a fitted state, is situated over an edge region on the upper side of the panel and is clamped against the respective edge region by means of the pin-shaped attachment member in order to fasten the panel against the support structure, wherein the clamping member has a peripheral edge, and in that the clamping member, at least in a pre-fitting state, is rotatable with respect to the pin-shaped attachment member in a plane at right angles to the pin-shaped attachment member, with the clamping member being rotatable with respect to a panel to be fitted or fitted on the support structure into an inactive position in which that portion of the peripheral edge which is turned towards the respective panel is not situated over the edge region of the panel, so that fitting a panel on or removing a panel from the support structure is made possible.

2. Attachment system according to claim 1, wherein said peripheral edge portion which, in the inactive position of the clamping member, does not extend over the edge region of the panel, is a straight edge portion.

3. Attachment system according to claim 2, wherein the peripheral edge is furthermore arch-shaped, preferably in the shape of an arc of a circle.

4. Attachment system according to claim 1, wherein the clamping member comprises a central bore through which the pin-shaped attachment member extends.

5. Attachment system according to claim 1, wherein a spacer is provided between the clamping member and the support structure, which spacer has a bore through which the pin-shaped attachment member extends.

6. Attachment system according to claim 5, wherein the spacer is integrally formed with the clamping member.

7. Attachment system according to claim 5, wherein the spacer is formed in the shape of a bush.

8. Attachment system according to claim 5, wherein the spacer has an axial length which is at least half the thickness of a panel to be attached and is not more than the thickness of the panel.

9. Attachment system according to claim 5, wherein the portion of the peripheral edge of the clamping member which, in the inactive position of the clamping member, does not extend over an edge region of a respective panel, is situated in the same plane as the corresponding side of the spacer.

10. Attachment system according to claim 1, wherein the clamping member is made from plastic.

11. Attachment system according to claim 5, wherein the clamping member and the spacer are integrally formed from plastic.

12. Attachment system according to claim 1, wherein the pin-shaped attachment member is provided with an external screw thread.

13. Attachment system according to claim 12, wherein the pin-shaped attachment member is in the form of a screw provided with a screw head, a bolt provided with a bolt head, or a threaded rod provided with a nut, in which the screw head, bolt head or nut engages with the side of the clamping member which is facing away from the support structure.

14. Attachment system according to claim 13, wherein the clamping member, on that side which is facing away from the support structure, is provided with an recess to accommodate a screw head, bolt head, nut or the like.

15. Attachment system according to claim 1, wherein the support structure comprises support profiled sections, wherein the pin-shaped members are connected to the support profiled section.

16. Attachment system according to claim 15, wherein the support profiled sections are designed as profiled-section rails of the type having a bottom, side walls which extend from the bottom and an upper side which is situated opposite the bottom and comprises two flanges, each of which extends inwards from a side wall and delimits a longitudinal slot.

17. Attachment system according to claim 16, wherein the pin-shaped attachment member is connected to the support profiled section by means of an attachment assembly comprising an elongate anchor part which, in one orientation parallel to the longitudinal slot of the support profiled section, fits through the longitudinal slot and, in one orientation transverse to the longitudinal slot, grips behind the flanges of the profiled section, and a bearing plate which, in use, is situated on the upper side of the flanges.

18. Attachment system according to claim 17, wherein the attachment assembly comprises a support which connects the anchor part and the bearing plate to one another.

19. Attachment system according to claim 18, wherein the support connects the anchor part and the bearing plate to one another in a resilient manner.

20. Attachment system according to claim 17, wherein the anchor part, at least in a pre-fitting state, is connected to the pin-shaped attachment member in a non-rotatable manner.

21. Attachment system according to claim 20, wherein the attachment assembly comprises a spring which is operational between the bearing plate and the pin-shaped attachment member, and in which the bearing plate and the anchor part can be moved away from one another counter to the spring force of the spring.

22. Attachment system according to claim 17, wherein the bearing plate is provided with a supporting member which is designed and fitted in such a manner that when the clamping member is clamped against the edge region of a solar panel by means of the pin-shaped attachment member, the supporting member supports the clamping member, or a part which is connected thereto, in such a manner that the clamping member cannot tilt away from said edge region.

23. Solar panel installation comprising an attachment system according to claim 1, as well as solar panels mounted on the attachment system.

24. Clamping member clearly intended for use with an attachment system according to claim 1.

25. Method for mounting several solar panels next to one another on a support structure, comprising the following method steps:
at least three pin-shaped attachment members together with clamping members coupled thereto are arranged on the support structure at such a distance from one another that a solar panel can be fitted between each pair of clamping members, with each of the clamping members being rotatable with respect to the associated pin-shaped member about an axis of rotation which runs parallel to or coincides with the centre axis of the pin-shaped attachment member, wherein the clamping member has a peripheral edge, and wherein the clamping member can be moved to an inactive position by rotation;
the clamping members associated with a first panel to be fitted are moved to an inactive position by rotation of the clamping member, in which position the portion of the peripheral edge of the respective clamping member which is turned towards the respective panel does not extend over the edge region of the panel;
the first solar panel is fitted against the support structure between the associated attachment members, wherein opposite edges of the panel are situated against the pin-shaped attachment members or against spacers extending around the attachment members;
the clamping members associated with the first panel are rotated from the inactive position to an active position in which they extend over the edge of the first panel and lock the first panel against the support structure, with the at least one clamping member, which is associated with the first panel and is also associated with a second panel to be fitted next to the first panel, being oriented in such a manner that it is in an inactive position with respect to the edge region of the second panel to be fitted;
the at least one other clamping member associated with the second panel to be fitted is rotated in such a manner that it is moved into the inactive position with respect to the second panel;
the second solar panel is fitted against the support structure between the associated attachment members, with opposite edges of the panel being situated against the pin-shaped attachment members or against spacers extending around the attachment members;
the at least one clamping member associated both with the first and with the second panel is rotated into an active position in which it extends over the edge of the first and the second panel and locks the first and second panel against the support structure;
the at least one other clamping member associated with the second panel is rotated into an active position in which it extends over the edge of the second panel and locks the second panel against the support structure.
